(19) United States
(12) Patent Application Publication
(10) Pub. No.: US 2023/0261156 A1
(43) Pub. Date: Aug. 17, 2023

(54) SEMICONDUCTOR ASSEMBLY

(71) Applicant: LITE-ON TECHNOLOGY CORPORATION, Taipei City (TW)

(72) Inventors: MIAO-SAN CHIEN, Hsinchu County (TW); Kai-Chieh Liang, New Taipei City (TW); Wei-Te Cheng, Taipei City (TW); KUO-MING CHIU, New Taipei City (TW)

(21) Appl. No.: 18/108,872

(22) Filed: Feb. 13, 2023

Related U.S. Application Data
(60) Provisional application No. 63/309,755, filed on Feb. 14, 2022.
(60) Provisional application No. 63/331,907, filed on Apr. 18, 2022.

(30) Foreign Application Priority Data
Oct. 21, 2022 (CN) 202211294105.3
Feb. 8, 2023 (CN) 202310089678.0

(51) Int. Cl. H01L 33/60; H01L 33/48

(52) U.S. Cl. CPC H01L 33/60; H01L 33/486; H01L 33/62

(57) ABSTRACT

A semiconductor assembly includes a substrate, a retaining wall, a light emitting unit, and a reflective layer. The substrate has a mounting surface. The retaining wall is disposed on the mounting surface and has an inner surface. An accommodation space is defined by the inner surface and the mounting surface. The light emitting unit is disposed in the accommodation space and disposed on the mounting surface. The light emitting unit has an upper light emitting surface and a side light emitting surface. The reflective resin layer is disposed in the accommodation space and disposed between the inner surface and the side light emitting surface. The reflective resin layer contains a based resin, a UV absorber, and reflective particles.

### CROSS-REFERENCE TO RELATED PATENT APPLICATION

This application claims the benefit of priorities to China Patent Application No. 202211294105.3, files on Oct. 21, 2022 and Application No. 202310089678.0, filed on Feb. 8, 2023 in People's Republic of China. The entire content of the above identified application is incorporated herein by reference.

This application claims the benefit of priorities to the U.S. Provisional Patent Application Ser. No. 63/309,755 filed on Feb. 14, 2022 and Ser. No. 63/331,907 filed on Apr. 18, 2022, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a semiconductor assembly, and more particularly to a semiconductor assembly that has good reliability.

### BACKGROUND OF THE DISCLOSURE

Light emitting dioxide (LED) has advantages of low energy consumption, long service life, and high luminous efficiency. By using different semiconductor materials, LED can generate various light that have different wavelengths. Therefore, conventional light sources have gradually been replaced by lighting equipment that is manufactured from LED.

Materials and metal electrodes in LED are easily to be oxidized by vapor and oxygen in the environment. Therefore, LED is usually encapsulated by a silicone resin acting as an encapsulant to prevent LED from contacting vapor and oxygen.

Compared to C—C bond (bond energy: 145 kcal/mol) in organic materials, Si—O bond (bond energy: 193.5 kcal/mol) in a silicone resin has a higher bond energy. However, breakages still may happen on the silicone resin at a working environment of high temperature or a high energy (such as UV). When the breakages happen, a transmittance of the silicone resin will decrease, which may negatively influence the luminous efficiency of the lighting equipment. In order to evaluate the reliability of the lighting equipment, the lighting equipment is operated with different power and measured by the Wet High Temperature Operating Life (WHTOL) test.

FIG. 11 shown a conventional semiconductor assembly which using a single silicone resin 80 as the encapsulant. In the conventional semiconductor assembly, a light emitting dioxide 90 is completely encapsulated by the silicone resin 80, and a dome-shape encapsulant is formed by the silicone resin 80. However, at a working environment of 90RH % and 60° C., the conventional semiconductor assembly (shown in FIG. 11) operated with a power of 18 mW cannot pass the WHTOL reliability test (i.e., a tolerance time being less than 500 hours). Moreover, gel cracking and luminous attenuation are occurred.

Therefore, how to enhance the reliability of the semiconductor assembly by improving the structure or the material of the semiconductor assembly has become one of the important issues to be solved in the industry. Accordingly, in the case of maintaining the luminous efficiency, the semiconductor assembly can be operated with high power and operated at a high temperature and a high humidity environment.

### SUMMARY OF THE DISCLOSURE

In response to the above-referenced technical inadequacy, the present disclosure provides a semiconductor assembly.

In one aspect, the present disclosure provides a semiconductor assembly. The semiconductor assembly includes a substrate, a retaining wall, a light emitting unit, and a reflective layer. The substrate has a mounting surface. The retaining wall is disposed on the mounting surface and has an inner surface. An accommodation space is defined by the inner surface and the mounting surface. The light emitting unit is disposed in the accommodation space and disposed on the mounting surface. The light emitting unit has an upper light emitting surface and a side light emitting surface. The reflective resin layer is disposed in the accommodation space and disposed between the inner surface and the side light emitting surface. The reflective resin layer contains a based resin, a UV absorber, and reflective particles.

In another aspect, the present disclosure provides a semiconductor assembly. The semiconductor assembly includes a substrate, a light emitting unit, a Zener chip, a first reflective layer, and a light transmitting layer. The substrate has a mounting surface. The light emitting unit is disposed on the mounting surface. The light emitting unit has an upper light emitting surface and a side light emitting surface. The Zener chip is disposed on the mounting surface. The Zener chip is encapsulated by the first reflective layer. The first reflective resin layer contains a first silicon-based resin, a UV absorber, and reflective particles. The light emitting unit, the Zener chip, and the first reflective resin layer are encapsulated by the light transmitting layer. The light transmitting layer contains a fluoropolymer.

In yet another aspect, the present disclosure provides a semiconductor assembly. The semiconductor assembly includes a substrate, a light emitting unit, a Zener chip, a first reflective layer, and a light transmitting layer. The substrate has a mounting surface. The mounting surface includes a center area and a peripheral area surrounding the center area. The light emitting unit is disposed on the center area. The light emitting unit has an upper light emitting surface and a side light emitting surface. The Zener chip is disposed on the peripheral area. The Zener chip is encapsulated by the first reflective layer. The first reflective resin layer contains a first silicon-based resin, a UV absorber, and reflective particles. The light transmitting layer is disposed on the center area, and the upper light emitting surface and the side light emitting surface are covered by the light transmitting layer. The light transmitting layer contains a fluoropolymer.

In yet another aspect, the present disclosure provides a semiconductor assembly. The semiconductor assembly includes a substrate, a light emitting unit, a Zener chip, a first reflective layer, and a light transmitting layer. The substrate has a mounting surface. The mounting surface includes a center area and a peripheral area surrounding the center area. The light emitting unit is disposed on the center area. The light emitting unit has an upper light emitting surface and a side light emitting surface. The Zener chip is disposed on the center area. The Zener chip is encapsulated by the first reflective layer. The first reflective resin layer contains a first silicon-based resin, a UV absorber, and reflective particles. The light transmitting layer is disposed on the center area, and the light emitting unit, the Zener chip, and the first reflective resin layer are covered by the light transmitting layer. The light transmitting layer contains a fluoropolymer.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a cross sectional view of a semiconductor assembly according to a first embodiment of the present disclosure;

FIG. 2 is a cross sectional view of the semiconductor assembly according to a second embodiment of the present disclosure;

FIG. 3 is a cross sectional view of the semiconductor assembly according to a third embodiment of the present disclosure;

FIG. 4 is a cross sectional view of the semiconductor assembly according to a fourth embodiment of the present disclosure;

FIG. 5 is a cross sectional view of the semiconductor assembly according to a fifth embodiment of the present disclosure;

FIG. 6 is a cross sectional view of the semiconductor assembly according to a sixth embodiment of the present disclosure;

FIG. 7 is a cross sectional view of the semiconductor assembly according to a seventh embodiment of the present disclosure;

FIG. 8 is a cross sectional view of the semiconductor assembly according to an eighth embodiment of the present disclosure;

FIG. 9 is a cross sectional view of the semiconductor assembly according to a ninth embodiment of the present disclosure;

FIG. 10 is a cross sectional view of the semiconductor assembly according to a tenth embodiment of the present disclosure; and

FIG. 11 is a side view of a conventional semiconductor assembly.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

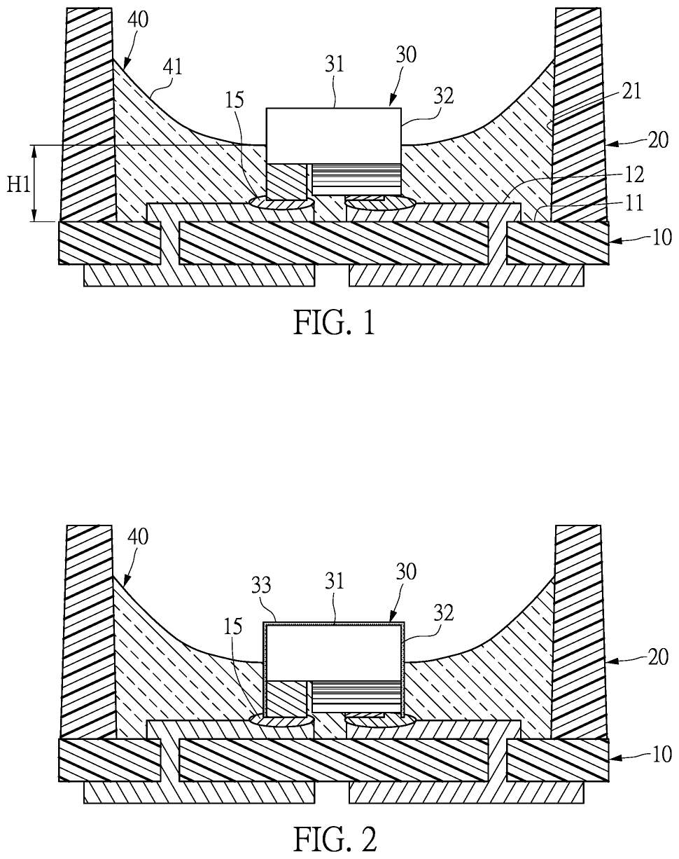

Referring to FIG. 1, the semiconductor assembly of the present disclosure includes a substrate 10, a retaining wall 20, a light emitting unit 30, and a reflective resin layer 40.

The substrate 10 has a mounting surface 11. A circuit structure 12 is disposed on the substrate 10. The light emitting unit 30 can be electrically connected with an outer circuit via the circuit structure 12. For example, the substrate 10 can be an aluminum nitride substrate or an aluminum oxide substrate, but the present disclosure is not limited thereto.

The retaining wall 20 is disposed on the mounting surface 11 and has an inner surface 21. An accommodation space is defined by the inner surface 21 and the mounting surface 11. In an exemplary embodiment, the inner surface 21 can be a roughened surface. The roughened surface can enhance the reflective effect of the retaining wall 20, thereby increasing the luminous efficiency of the semiconductor assembly. In some unshown exemplary embodiments, the substrate 10 and the retaining wall 20 can be integrally formed.

The light emitting unit 30 is disposed in the accommodation space and disposed on the mounting surface 11. Specifically, the light emitting unit 30 is fixed on the mounting surface 11 via a die bonding adhesive 15 (as shown in FIG. 1). A material of the die bonding adhesive 15 can be a silver solder paste, a gold-tin alloy (AuSn) solder paste, or a tin solder paste. The light emitting unit 30 has an upper light emitting surface 31 and a side light emitting surface 32. The upper light emitting surface 31 is connected with the side light emitting surface 32. The upper light emitting surface 31 is a surface of the light emitting unit 30 that is opposite to the mounting surface 11.

The light emitting unit 30 can include one or more than one LED chips. Types of the LED chips can be, but not limited to, horizontal LED chips, vertical LED chips, or flip-chip LED chips.

In an exemplary embodiment, the light emitting unit 30 can generate UV light beam. In other words, the light emitting unit 30 can include UV LED chips or LED chips that can convert light into UV light.

In an exemplary embodiment, the light emitting unit 30 can be optionally covered by a protection layer 33 (as shown in FIG. 2). In other words, the protection layer 33 is disposed on the upper light emitting surface 31 and the side light emitting surface 32. The protection layer 33 includes a light-transmitting resin. The protection layer 33 can prevent the light emitting unit 30 from contacting vapor in the environment.

The reflective resin layer 40 is disposed in the accommodation space and disposed between the inner surface 21 and the side light emitting surface 32. It should be noted that the upper light emitting surface 31 is not covered by the reflective resin layer 40. Relative to the mounting surface 11, a height of the reflective resin layer 40 near the side light emitting surface 32 is lower than or equal to a height of the upper light emitting surface 31.

In an exemplary embodiment, the reflective resin layer 40 has a listric surface 41 (shown in FIG. 1) between the retaining wall 20 and the light emitting unit 30. In other words, relative to the mounting surface 11, the height of the reflective resin layer 40 near the side light emitting surface 32 is lower than a height of the reflective resin layer 40 near the inner surface 21. Due to the listric surface 41, the reflective effect of the reflective resin layer 40 can be enhanced. In addition, the listric surface 41 can prevent a UV light beam from re-entering the reflective resin layer 40, such that the reliability of the semiconductor assembly can be enhanced.

In another exemplary embodiment, the reflective resin layer 40 can also have a concave surface between the retaining wall 20 and the light emitting unit 30. In other words, relative the mounting surface 11, the height of the reflective resin layer 40 near the side light emitting surface 32 is higher than the height of the reflective resin layer 40 near the inner surface 21. However, the present disclosure is not limited thereto.

The reflective resin layer 40 is a light-transmitting layer which is permeable to light beam. When a thickness H1 of the reflective resin layer 40 is too thick, the luminous efficiency of the semiconductor assembly is negatively influenced. Therefore, the thickness H1 of the reflective resin layer 40 should be thinner than 300 μm. For the sufficient UV reflection effect, the thickness H1 of the reflective resin layer 40 should be thicker than 50 μm. In the specification, the thickness H1 of the reflective resin layer 40 refers to a thickness of the reflective resin layer 40 near the side light emitting surface 32 relative to the mounting surface 11.

The reflective resin layer 40 has functions of reflecting UV light and absorbing UV light. A material of the reflective resin layer 40 contains a based resin, a UV absorber, and reflective particles.

The based resin is a silicon-based resin. Specifically, the silicon-based resin can optionally be a silicon-based resin including methyl group or a thermosetting silicon-based resin according to various requirements. For example, the based resin can be a methyl silicon resin, a methyl phenyl vinyl silicon resin, or a combination thereof.

The UV absorber can absorb UV light, especially for UV light that has a wavelength ranging from 250 nm to 400 nm and convert light energy into heat energy. When the based resin is exposed to light, the UV absorber can prevent the based resin from bond breakages through a chemically absorption mechanism.

The reflective particles can enhance the reflectivity of the reflective resin layer 40. When the based resin is exposed to light, the reflective particles can prevent the based resin from bond breakages through a physical reflection mechanism. Average particular size of the reflective particles ranges from 0.2 μm to 20 μm. When the particular size of the reflective particles is too large, the reflective particles are difficult to mix with other components, thereby leading to a poor reflection effect. When the particular size of the reflective particles is too small, the reflective particles are easily to settle down, which causes the reflective resin layer 40 has a poor reflection effect at bottom. For example, the reflective particles can be PTFE particles or zirconium dioxide particles. Preferably, the reflective particles are PTFE particles. However, the present disclosure is not limited thereto.

In an exemplary embodiment, based on a total weight of the based resin being 100 phr, an amount of the UV absorber ranges from 0.1 phr to 15 phr. Excessive UV absorber may absorb most of light, thereby weakening the luminous efficiency of the semiconductor assembly. In addition, a solvent to dissolve the UV absorber tends to react with the silicon-based resin so that the silicon-based resin has difficulty in curing. Insufficient UV absorber cannot avoid the silicon-based resin from being degraded by UV light, and then the reliability of the semiconductor assembly is negatively influenced.

In an exemplary embodiment, based on the total weight of the based resin being 100 phr, an amount of the reflective particles ranges from 5 phr to 75 phr; preferably, the amount of the reflective particles ranges from 25 phr to 50 phr. Excessive reflective particles causes a high viscosity so that the material of the reflective resin layer 40 has difficulty while dispensing. Insufficient reflective particles cannot enhance the luminous efficiency of the semiconductor assembly.

In addition to the based resin, the UV absorber, and the reflective particles, the reflective resin layer 40 can further include a hindered amine light stabilizer (HALS). The hindered amine light stabilizer can repair bond breakages, so that the hindered amine light stabilizer can also prevent the based resin from bond breakages.

In an exemplary embodiment, based on the total weight of the based resin being 100 phr, an amount of the HALS ranges from 0.1 phr to 15 phr. A solvent to dissolve the HALS tends to react with the silicon-based resin so that excessive HALS causes the silicon-based resin having difficulty while curing. Insufficient HALS cannot improve the reliability of the semiconductor assembly.

### First Embodiment

Referring to FIG. 1, the semiconductor assembly of a first embodiment of the present disclosure includes: the substrate 10, the retaining wall 20, the light emitting unit 30, and the reflective resin layer 40.

The substrate 10 is an aluminum nitride substrate. The retaining wall 20, the light emitting unit 30, and the reflective resin layer 40 are disposed on the mounting surface 11 of the substrate 10. The light emitting unit 30 is surrounded by the retaining wall 20. The reflective resin layer 40 is formed between the retaining wall 20 and the light emitting unit 30.

Specifically, the reflective resin layer 40 contacts the inner side surface 21 of the retaining wall 20 and the side light emitting surface 32 of the light emitting unit 30, but the upper light emitting surface 31 is not covered by the reflective resin layer 40. Relative to the mounting surface 11, the height of the reflective resin layer 40 near the side light emitting surface 32 is lower than or equal to the height of the upper light emitting surface 31.

The reflective resin layer 40 has a listric surface which is distant from the mounting surface 11. Relative to the mounting surface 11, the height of the reflective resin layer 40 near the side light emitting surface 32 is lower than the height of the reflective resin layer 40 near the upper light emitting surface 31. Accordingly, the reflection effect and the reliability of the semiconductor assembly can be enhanced.

The light emitting unit 30 is disposed on the circuit structure 12 via the die bonding adhesive 15 so as to electrically connect the light emitting unit 30 with the circuit structure 12. The circuit structure 12 is embedded in the substrate 10, and partially exposed from the mounting surface 11 of the substrate 10 and partially exposed from an opposite surface of the mounting surface 11. Therefore, the light emitting unit 30 can be electrically connected with an outer circuit to supply power to the semiconductor assembly.

In order to prove that the semiconductor assembly of the present disclosure has a high reliability, the semiconductor assemblies in Examples 1 to 2 and Comparative Examples 1 to 5 are manufactured according to the first embodiment. The luminous efficiency and the reliability of the semiconductor assembly are measured and listed in Table 1.

In the luminous efficiency test, the semiconductor assembly is powered with 0.3 W to generate a light beam. A light intensity of the semiconductor assembly of Comparative Example 1 is defined as 100%, so as to evaluate the relationship between the light intensity and the reliability of the semiconductor assembly.

In the reliability test, the semiconductor assembly generates a light beam at a room temperature environment (25° C.) and at a warm and damp environment (60° C., humidity: 90%), so as to evaluate the reliability of the semiconductor assembly. After 500 hours of continuous operation, the semiconductor assembly that can maintain its original structure and have a luminous attenuation lower than 30% is marked with the term “PASS”; the semiconductor assembly that is damaged or peeled off and have a luminous attenuation higher than or equal to 30% is marked with the term “FAIL”.

The difference between Examples 1 to 2 and Comparative Examples 1 to 5 is that the components of the reflective resin layer 40. Specifically, the reflective resin layer 40 in Examples 1 to 2 contains the based resin, the UV absorber, and the reflective particles. In addition, the reflective resin layer 40 in Example 2 further contains the HALS. The reflective resin layer 40 in Comparative Examples 1 to 5 does not contain the UV absorber and the reflective particles at the same time. Specific components of the reflective resin layer 40 in Examples 1 to 2 and Comparative Examples 1 to 5 are listed in Table 1. In Examples 1 to 2 and Comparative Examples 1 to 5, the reflective particles are polytetrafluoroethylene (PTFE) particles, the UV absorber is 2-(2,4-dihydroxyphenyl)-4,6-bis(2,4-dimethyl-phenyl)-1,3,5-triazine, and the HALS is bis(2,2,6,6-tetramethyl-1-(octyloxy)-4-piperidinyl) ester. The thickness H1 of the reflective resin layer 40 ranges from 200 μm to 300 μm.

When the thickness H1 of the reflective resin layer 40 is too thick, the reflective effect of the reflective resin layer 40 will be reduced instead, and the light beam reflected by the reflective resin layer 40 may enter the light transmitting layer (i.e., the first light transmitting layer and the second light transmitting layer), which causes crack in the light transmitting layer. When the thickness H1 of the reflective resin layer 40 is too thin, the reflective effect of the reflective resin layer 40 will be similar to the reflective effect of the light transmitting layer, and the reliability of the semiconductor assembly cannot be enhanced.

TABLE 1

| | | Example | | Comparative Example | | | | |
|---|---|---|---|---|---|---|---|---|
| (phr) | | 1 | 2 | 1 | 2 | 3 | 4 | 5 |
| Reflective | Based resin | 100 | 100 | 100 | 100 | 100 | 100 | 100 |
| resin layer | Reflective | 40 | 40 | 40 | — | — | — | 40 |
| | particles | | | | | | | |
| | UV | 10 | 10 | — | 10 | — | 10 | — |
| | absorber | | | | | | | |
| | HALS | — | 10 | — | — | 10 | 10 | 10 |
| Properties | Luminous | 85% | 85% | 100% | 61% | 88% | 61% | 100% |
| of semi- | efficiency | | | | | | | |
| conductor | test | | | | | | | |
| assembly | Reliability | PASS | PASS | FAIL | PASS | FAIL | PASS | FAIL |
| | test | (1500 hours | (2000 hours | (168 hours | (500 hours | (bond | (500 hours | (168 hours |
| | | reliability | reliability | reliability | reliability | breakage) | reliability | reliability |
| | | test) | test) | test) | test) | | test) | test) |

According to the result of Table 1, for containing the based resin, the UV absorber, and the reflective particles, the reflective resin layer 40 can enhance the reliability of the semiconductor assembly, and the luminous efficiency of the semiconductor assembly can be adequately maintained.

Specifically, the semiconductor assembly in Example 1 can pass the 1500 hours reliability test with a light emitting power of less than 40 mW. The semiconductor assembly in Example 2 can pass the 2000 hours reliability test with a light emitting power of less than 40 mW. The semiconductor assembly in Comparative Example 1 cannot pass the 168 hours reliability test with a light emitting power of less than 40 mW. The semiconductor assembly in Comparative Example 2 can pass the 500 hours reliability test with a light emitting power of less than 40 mW, but the luminous efficiency is low and only reaches 61% relative to Comparative Example 1. Bond breakages occur in the semiconductor assembly in Comparative Example 3 with a light emitting power of less than 10 mW, so that the semiconductor assembly in Comparative Example 3 cannot pass the reliability test. The semiconductor assembly in Comparative Example 4 can pass the 500 hours reliability test emitting light with a light emitting power of less than 20 mW. The semiconductor assembly in Comparative Example 5 cannot pass the 168 hours reliability test with a light emitting power of less than 40 mW.

In order to prove that the semiconductor assembly of the present disclosure can endure a harsh temperature environment, the semiconductor assembly in Examples 2 and 3 are processed a thermal shock test, and the results are listed in Table 2. The semiconductor assembly in Examples 2 and 3 is manufactured according to the first embodiment.

In Examples 2 and 3, the reflective particles, the UV absorber, and the HALS are the same as those mentioned above, so it is not repeated herein. The based resin used in Example 2 is a silicon-based resin that has a low hardness (cured hardness: Shore A52). The based resin used in Example 3 is a silicon-based resin that has a high hardness (cured hardness: Shore D35).

Specific components of the reflective resin layer 40 in Examples 2 and 3 are listed in Table 2. The thickness H1 of the reflective resin layer 40 ranges from 200 μm to 300 μm.

In the thermal shock test, the endurance of the semiconductor assembly at harsh temperature environment is evaluated within a temperature range from −40° C. to 125° C. by a changing rate of 40° C. per minute. After 1000 cycles of temperature changes, the term “PASS” represents that the structure of the semiconductor assembly can still be maintained intact, and the term “FAIL” represents that the structure of the semiconductor assembly is peeled off or damaged.

TABLE 2

| | | Example | |
|---|---|---|---|
| (phr) | | 2 | 3 |
| Reflective resin layer | Based resin | 100 | 100 |
| | Reflective particles | 40 | 30 |
| | UV absorber | 10 | 10 |
| | HALS | 10 | — |
| Property of | Thermal shock test | PASS | PASS |
| semiconductor assembly | | | |

According to the result of Table 2, the semiconductor assembly of the present disclosure can endure the harsh temperature environment. Specifically, the semiconductor assembly in Examples 2 and 3 can have a complete structure after 1000 cycles of temperature change.

### Second Embodiment

Referring to FIG. 2, the semiconductor assembly of a second embodiment of the present disclosure is similar to the semiconductor assembly of the first embodiment (FIG. 1). The semiconductor assembly includes the substrate 10, the retaining wall 20, the light emitting unit 30, and the reflective resin layer 40. The difference between the second embodiment and the first embodiment is that: the light emitting unit 30 is covered by a protection layer 33.

The protection layer 33 is formed on the upper light emitting surface 31 and the side light emitting surface 32, so as to protect the light emitting unit 30. In addition, the protection layer 33 can prevent the light emitting unit 30 from contacting vapor in the environment. A material of the protection layer 33 includes a light-transmitting resin, such as a fluoropolymer resin.

### Third Embodiment

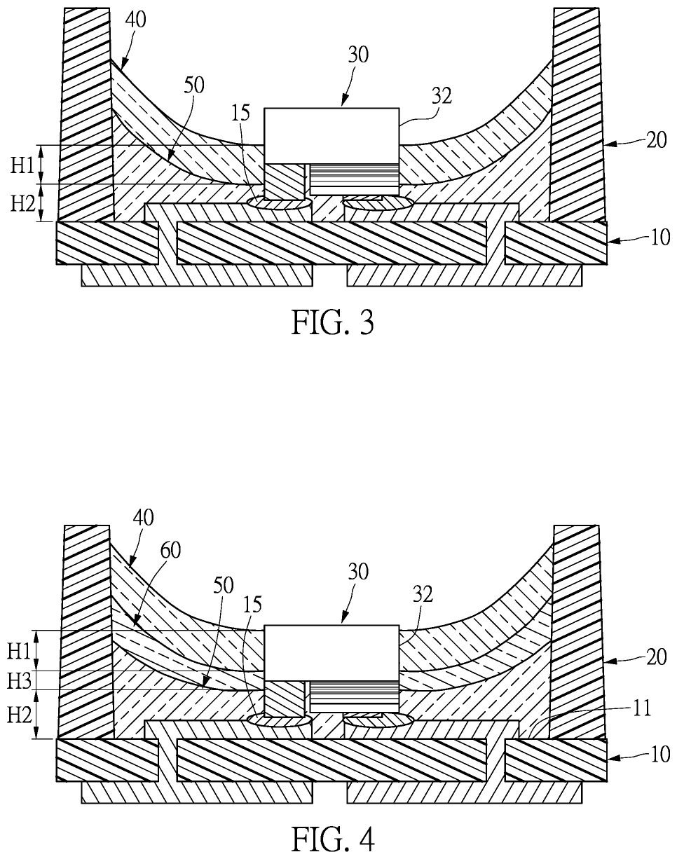

Referring to FIG. 3, the semiconductor assembly of a third embodiment of the present disclosure is similar to the semiconductor assembly of the first embodiment (FIG. 1). The semiconductor assembly includes the substrate 10, the retaining wall 20, the light emitting unit 30, and the reflective resin layer 40. The difference between the third embodiment and the first embodiment is that: the semiconductor assembly further includes a first light transmitting layer 50.

The first light transmitting layer 50 is disposed on the mounting surface 11 and disposed between the substrate 10 and the reflective resin layer 40. The first light transmitting layer 50 is permeable to UV light and can absorb few amounts of UV light. Relative to mounting surface 11, a thickness H2 of the first light transmitting layer 50 near the side light emitting surface 32 ranges from 50 μm to 100 μm.

A material of the first light transmitting layer 50 includes a first based resin and a UV absorber. Based on a total weight of the first based resin being 100 phr, an amount of the UV absorber ranges from 0.1 phr to 2 phr. The first based resin can be a silicon-based resin. Specifically, the first based resin can optionally be a silicon-based resin containing a methyl group or a thermosetting silicon-based resin according to different requirements.

In an exemplary embodiment, the first light transmitting layer 50 can further include a HALS. An addition of the HALS can further enhance UV absorbing effect of the first light transmitting layer 50. Based on the total weight of the first based resin being 100 phr, an amount of the HALS ranges from 0.1 phr to 15 phr.

In order to prove that the semiconductor assembly of the present disclosure has a high reliability, the semiconductor assembly in Example 5 is manufactured according to the third embodiment. Luminous efficiency and the reliability of the semiconductor assembly in Example 5 are measured and listed in Table 3. In the luminous efficiency test, the light intensity of the semiconductor assembly in Comparative Example 1 is defined as 100%.

In Example 5, the reflective particles, the UV absorber, and the HALS are the same as those mentioned above, so it is not repeated herein. Specific components of the reflective resin layer 40 and the first light transmitting layer 50 are listed in Table 3. The thickness H1 of the reflective resin layer 40 ranges from 200 μm to 300 μm. The thickness H2 of the first light transmitting layer 50 ranges from 5 μm to 150 μm. If the thickness H2 of the first light transmitting layer 50 is too thick, a UV light beam tends to be absorbed by the first light transmitting layer 50, such that the luminous efficiency of the semiconductor assembly is decreased. If the thickness H2 of the first light transmitting layer 50 is too thin, the manufacturing process has difficulty in undergoing and quality control.

TABLE 3

| (phr) | | Example 1 | Example 5 |
|---|---|---|---|
| Reflective resin | Based resin | 100 | 100 |
| layer | Reflective | 40 | 40 |
| | particles | | |
| | UV absorber | 10 | 10 |
| | HALS | — | — |
| First light | First based | — | 100 |
| transmitting layer | resin | | |
| | UV absorber | — | 1 |
| Property of | Luminous | 85% | 78% |
| assembly | efficiency test | | |
| semiconductor | Reliability test | PASS (1500 hours | PASS (500 hours |
| | | reliability test) | reliability test) |

According to the result of Table 3, due to the reflective resin layer 40 and the first light transmitting layer 50, the reliability of the semiconductor assembly can be enhanced and the luminous efficiency of the semiconductor assembly can be adequately maintained. Specifically, the semiconductor assembly in Example 5 can pass the 500 hours reliability test with a light emitting power of less than 40 mW.

### Fourth Embodiment

Referring to FIG. 4, a cross sectional view of the semiconductor assembly of a fourth embodiment of the present disclosure is shown in FIG. 4. The semiconductor assembly of a fourth embodiment of the present disclosure is similar to the semiconductor assembly of the third embodiment (FIG. 3). The semiconductor assembly includes the substrate 10, the retaining wall 20, the light emitting unit 30, the reflective resin layer 40, and the first light transmitting layer 50. The difference between the fourth embodiment and the third embodiment is that: the semiconductor assembly further includes a second light transmitting layer 60.

The second light transmitting layer 60 is disposed on the mounting surface 11, and disposed between the substrate 10 and the first light transmitting layer 50. The second light transmitting layer 60 absorbs most of the UV light. Relative to the mounting surface 11, a thickness H3 of the second light transmitting layer 60 near the side light emitting surface 32 ranges from 70 μm to 150 μm.

A material of the second light transmitting layer 60 includes a second based resin and a UV absorber. A concentration of the UV absorber in the second light transmitting layer 60 is higher than a concentration of the UV absorber in the first light transmitting layer 50. Based on a total weight of the second based resin being 100 phr, an amount of the UV absorber ranges from 5 phr to 15 phr. The second based resin is a silicon-based resin. Specifically, the second based resin can optionally be a silicon-based resin that containing a methyl group or a thermosetting silicon-based resin according to different requirements. The UV absorber can absorb UV light, especially for UV light that has a wavelength ranging from 250 nm to 400 nm. When the second based resin is exposed to light, the UV absorber can prevent the second based resin from bond breakages through a chemically absorption mechanism.

In order to prove that the semiconductor assembly of the present disclosure has a high reliability, the semiconductor assembly in Examples 6 and 7 are manufactured according to the fourth embodiment. Luminous efficiency and the reliability of the semiconductor assembly in Examples 6 and 7 are measured and listed in Table 4. In the luminous efficiency test, the light intensity of the semiconductor assembly in Comparative Example 1 is defined as 100%.

In Examples 6 and 7, the reflective particles, the UV absorber, and the HALS are the same as those mentioned above, so it is not repeated herein. Specific components of the reflective resin layer 40, the first light transmitting layer 50, and the second light transmitting layer 60 in Examples 6 and 7 are listed in Table 4. The thickness H1 of the reflective resin layer 40 ranges from 200 μm to 300 μm. The thickness H2 of the first light transmitting layer 50 ranges from 100 μm to 200 μm. The thickness H3 of the second light transmitting layer 60 is thinner than 100 μm. If the thickness H3 of the second light transmitting layer 60 is too thick, a space for the reflective resin layer 40 will be compressed, and then the luminous efficiency of the semiconductor assembly is decreased. If the thickness H3 of the second light transmitting layer 60 is too thin, the reliability of the semiconductor assembly cannot be enhanced.

TABLE 4

| | | Example | | | |
|---|---|---|---|---|---|
| (phr) | | 1 | 5 | 6 | 7 |
| Reflective resin | Based resin | 100 | 100 | 100 | 100 |
| layer | Reflective | 40 | 40 | 40 | 40 |
| | particles | | | | |
| | UV absorber | 10 | 10 | 1 | 1 |
| | HALS | — | — | — | 1 |
| First light | First based resin | — | 100 | 100 | 100 |
| transmitting layer | UV absorber | — | 1 | 1 | 1 |
| | HALS | — | — | — | 1 |
| Second light | Second based | — | — | 100 | 100 |
| transmitting layer | resin | | | | |
| | UV absorber | — | — | 10 | 10 |
| | HALS | — | — | — | 10 |
| Property of | Luminous | 85% | 78% | 92% | 93% |
| semiconductor | efficiency test | | | | |
| assembly | Reliability test | PASS | PASS | PASS | PASS |
| | | (1500 hours | (500 hours | (1000 hours | (1500 hours |
| | | reliability | reliability | reliability | reliability |
| | | test) | test) | test) | test) |

According to the result of Table 4, due to the reflective resin layer 40, the first light transmitting layer 50, and the second light transmitting layer 60, the reliability of the semiconductor assembly can be enhanced and the luminous efficiency of the semiconductor assembly can be adequately maintained. Specifically, the semiconductor assembly in Example 6 can pass the 1000 hours reliability test with a light emitting power of less than 40 mW. The semiconductor assembly in Example 7 can pass the 1500 hours reliability test with a light emitting power of less than 40 mW.

Passive components, such as Zener chips, are often mounted on the semiconductor assembly. Common passive components will absorb the light beam emitted by the light emitting unit. Therefore, the present disclosure proposes a solution of covering or shielding the passive components by reflective resins to reduce light absorption effect of the passive components. The following describes the solution in detail with reference to following fifth embodiment to tenth embodiment.

### Fifth Embodiment

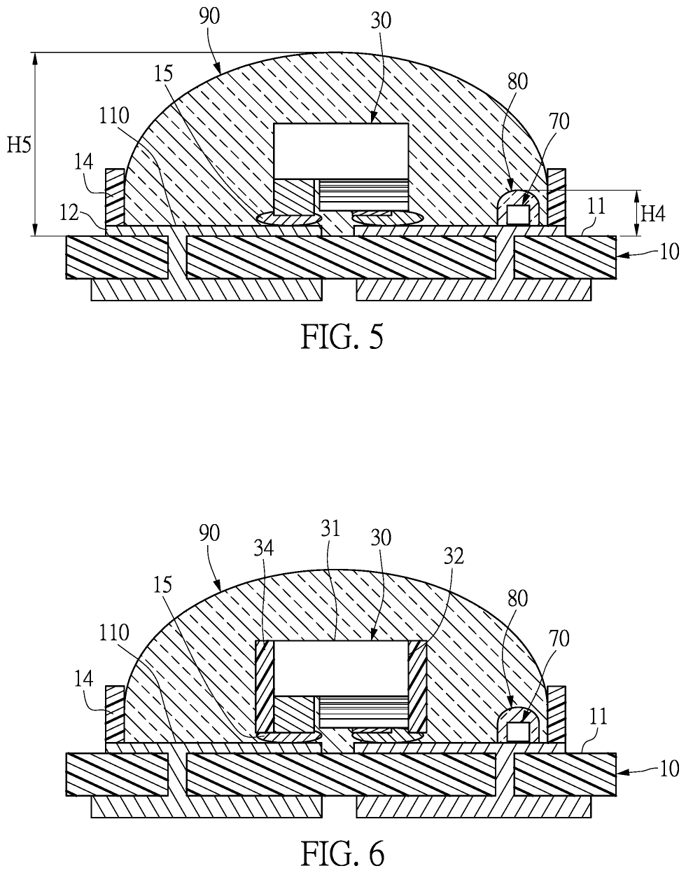

Referring to FIG. 5, the semiconductor assembly of a fifth embodiment includes the substrate 10, the light emitting unit 30, a Zener chip 70, a first reflective resin layer 80, and a light transmitting layer 90.

A circuit structure 12 is disposed on the mounting surface 11 of the substrate 10. The circuit structure 12 is embedded in the substrate 10, and partially exposed from the mounting surface 11 of the substrate 10 and partially exposed from an opposite surface of the mounting surface 11.

The light emitting unit 30 is fixed on the circuit structure 12 via the die bonding adhesive 15 and is electrically connected with the circuit structure 12. A material of the die bonding adhesive 15 can be a silver solder paste, a gold-tin alloy (AuSn) solder paste, or a tin solder paste. Accordingly, the light emitting unit 30 can be electrically connected with an outer circuit via the circuit structure 12 so as to supply power to the semiconductor assembly.

An outer limiter 14 is disposed on the mounting surface 11 of the substrate 10. In an exemplary embodiment, the outer limiter 14 is winded around on the mounting surface 11 so as to form a region 110. Due to the disposition of the outer limiter 14, the light transmitting layer 90 can only formed in the region 110.

The outer limiter 14 can be a metal material or a plastic material. For example, a material of the outer limiter 14 can be copper, gold, or other metals, or an epoxy resin or a silicon resin. When the material of the outer limiter 14 is a metal material, the outer limiter 14 can be formed by electroplating. When the material of the outer limiter 14 is a plastic material, the outer limiter 14 can be formed by molding or other plastic processes. However, the present disclosure is not limited thereto.

In an exemplary embodiment, a diameter of the outer limiter 14 ranges from 3 mm to 3.5 mm. Preferably, the diameter of the outer limiter 14 ranges from 3.2 mm to 3.25 mm. In addition, a height of the outer limiter 14 is higher than a position of a light emitting layer of the light emitting unit 30 and is higher than a height of the Zener chip 70.

The light emitting unit 30 is disposed on the mounting surface 11 and disposed in the region 110. The structure of the light emitting unit 30 is similar to that in the first embodiment, so it is not repeated herein.

The Zener chip 70 is disposed on the mounting surface 11 and disposed in the region 110. The Zener chip 70 can prevent the light emitting unit 30 from breakdown by a reverse current. The disposition of the Zener chip 70 can protect a circuit and a assembly.

The Zener chip 70 is encapsulated by the first reflective resin layer 80. The first reflective resin layer 80 has a dome-shaped surface formed on the mounting surface 11. The first reflective resin layer 80 is disposed in the circular region 110. The first reflective resin layer 80 can not only reduce the light absorption effect of the Zener chip 70 but also protect the Zener chip 70. Specifically, the first reflective resin layer 80 can protect the Zener chip 70 from peeling off and damaging during a high temperature baking process or a molding process. Accordingly, the first reflective resin layer 80 can enhance the reliability of the semiconductor assembly.

A material of the first reflective resin layer 80 includes a first silicon-based resin, UV absorber, and reflective particles.

Specifically, the silicon-based resin can optionally be a silicon-based resin including methyl group or a thermosetting silicon-based resin according to various requirements. For example, the first silicon-based resin can be a methyl silicon resin, a methyl phenyl vinyl silicon resin, or a combination thereof. The UV absorber and the reflective particles are the same as those mentioned above, so it is not repeated herein.

In an exemplary embodiment, based on a total weight of the first silicon-based resin being 100 phr, an amount of the UV absorber in the first reflective resin layer 80 ranges from 0.1 phr to 2 phr, such as 0.2 phr, 0.4 phr, 0.6 phr, 0.8 phr, 1.0 phr, 1.2 phr, 1.4 phr, 1.6 phr, or 1.8 phr.

In an exemplary embodiment, based on the total weight of the first silicon-based resin being 100 phr, an amount of the reflective particles in the first reflective resin layer 80 ranges from 5 phr to 75 phr, such as 15 phr, 25 phr, 35 phr, 45 phr, 55 phr, or 65 phr.

In addition to the first silicon-based resin, the UV absorber, and the reflective particles, the first reflective resin layer 80 can further include a hindered amine light stabilizer (HALS).

In an exemplary embodiment, based on a total weight of the first silicon-based resin being 100 phr, an amount of the HALS in the first reflective resin layer 80 ranges from 0.1 phr to 15 phr, such as 3 phr, 6 phr, 9 phr, or 12 phr.

Relative to the mounting surface 11, a thickness H4 of the first reflective resin layer 80 can range from 150 μm to 200 μm, such as 160 μm, 170 μm, 180 μm, or 190 μm.

The light transmitting layer 90 is disposed on the mounting surface 11 and disposed in the region 110. The light emitting unit 30, the Zener chip 70, and the first reflective resin layer 80 are encapsulated by the light transmitting layer 90. The light transmitting layer 90 has a dome-shaped surface formed on the mounting surface 11. The light transmitting layer 90 can protect the light emitting unit 30 and the Zener chip 70 and further enhance the reliability of the semiconductor assembly. A material of the light transmitting layer 90 includes a fluoropolymer. Relative to the mounting surface 11, the thickness H4 of the first reflective resin layer 80 ranges from 150 μm to 200 μm. If the thickness H4 of the first reflective resin layer 80 is too thick, a space for the light transmitting layer 90 will be compressed, and then the luminous efficiency of the semiconductor assembly is decreased. If the thickness H4 of the first reflective resin layer 80 is too thin, the first reflective resin layer 80 cannot effectively protect the Zener chip 70, and the reliability of the semiconductor assembly cannot be enhanced.

A thickness H5 of the light transmitting layer 90 can range from 500 μm to 850 μm. For example, the thickness H5 of the light transmitting layer 90 can be 550 μm, 600 μm, 650 μm, 700 μm, 750 μm, or 800 μm.

### Sixth Embodiment

Referring to FIG. 6, the semiconductor assembly of a sixth embodiment of the present disclosure is similar to the semiconductor assembly of the fifth embodiment (FIG. 5). The semiconductor assembly includes the substrate 10, the light emitting unit 30, a Zener chip 70, a first reflective resin layer 80, and a light transmitting layer 90. The difference between the sixth embodiment and the fifth embodiment is that: the light emitting unit 30 is surrounded by a reflective layer 34.

The reflective layer 34 is disposed on the side light emitting surface 32 of the light emitting unit 30 so as to concentrate the light beam emitted from the light emitting unit 30. Moreover, the reflective layer 34 can protect the light emitting unit 30 from contacting vapor in the environment. A material of the reflective layer 34 includes a light transmitting silicon resin and reflective particles, such as a silicon-based resin and PTFE particles.

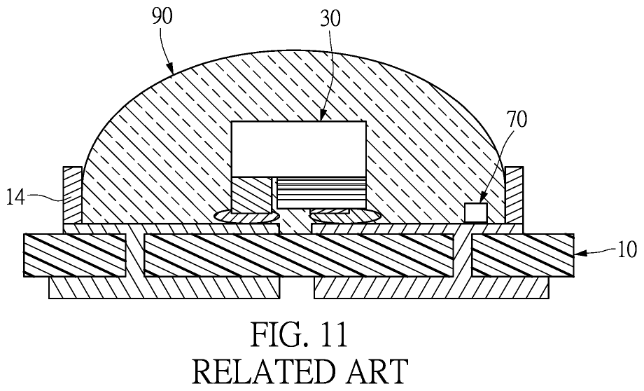

In order to prove that the semiconductor assembly of the present disclosure has a high reliability, the semiconductor assembly in Examples 8 and 9 are respectively manufactured according to the fifth embodiment and the sixth embodiment. The semiconductor assembly in Comparative Example 6 is manufactured according to the structure shown in FIG. 11.

The difference between the semiconductor assemblies in Comparative Example 6 and Examples 8 and 9 is that the first reflective resin layer 80 is absent from the semiconductor assemblies in Comparative Example 6. In other words, the Zener chip 70 in Comparative Example 6 is not encapsulated by the first reflective resin layer 80.

In Examples 8 and 9, the reflective particles, the UV absorber, and the HALS are the same as those mentioned above, so it is not repeated herein. Specific components of the first reflective resin layer 80 in Examples 8 and 9 are listed in Table 5. The material of the light transmitting layer 90 in Examples 8 and 9 and Comparative Example 6 is a fluoropolymer. Luminous efficiency and the reliability of the semiconductor assembly in Examples 8 and 9 and Comparative Example 6 are measured and listed in Table 5. In the luminous efficiency test, the light intensity of the semiconductor assembly in Comparative Example 6 is defined as 100%.

TABLE 5

| | | | Exam- | Exam- | Comparative |
|---|---|---|---|---|---|
| (phr) | | | ple 8 | ple 9 | Example 6 |
| First | First silicon-based resin | | 100 | 100 | — |
| reflective | Reflective particles | | 40 | 40 | — |
| resin layer | UV absorber | | 1 | 1 | — |
| | HALS | | 1 | 1 | — |
| Reflective | Light transmitting | | — | 60 | — |
| layer | silicon resin | | | | |
| | Reflective particles | | — | 40 | — |
| Property | Luminous efficiency test | | 102% | 105% | 100% |
| of semi- | Reliability | 0 hours | 100% | 100% | 100% |
| conductor | test | 168 hours | 96.3% | 95.8% | 95.3% |
| assembly | | 336 hours | 93.1% | 92.3% | 91.1% |
| | | 504 hours | 90.2% | 89.5% | 89.8% |
| | | 672 hours | 85.8% | 86.2% | 85.6% |
| | | 840 hours | 84.3% | 84.4% | 83.1% |
| | | 1008 hours | 83.2% | 83.8% | 82.07% |

According to the result of Table 5, due to the first reflective layer 80 encapsulating the Zener chip 70, the reliability of the semiconductor assembly can be enhanced and the luminous efficiency of the semiconductor assembly can be adequately maintained. The disposition of the reflective layer 34 surrounding the light emitting unit 30 can protect the light emitting unit 30 and further enhance the luminous efficiency and the reliability of the semiconductor assembly.

### Seventh Embodiment

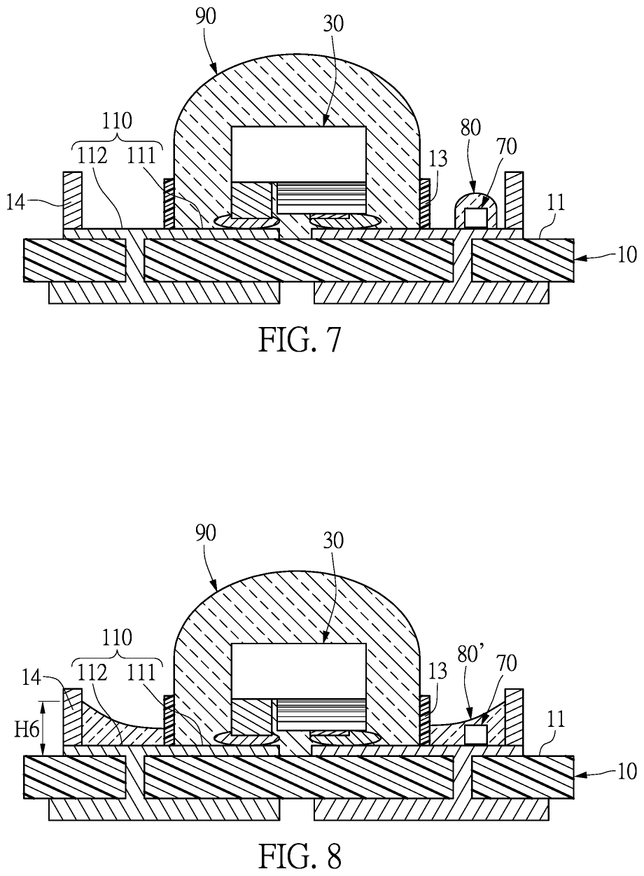

Referring to FIG. 7, the semiconductor assembly of a seventh embodiment of the present disclosure is similar to the semiconductor assembly of the fifth embodiment (FIG. 5). The semiconductor assembly includes the substrate 10, the light emitting unit 30, a Zener chip 70, a first reflective resin layer 80, and a light transmitting layer 90.

The difference between the seventh embodiment and the fifth embodiment is that an inner limiter 13 is disposed on the substrate 10, such that the circular region 110 is divided into a center area 111 and a periphery area 112. The light transmitting layer 90 is disposed in the center area 111. It should be noted that the light emitting unit 30 is encapsulated by the light transmitting layer 90; while, the Zener chip 70 and the first reflective resin layer 80 are not encapsulated by the light transmitting layer 90.

The inner limiter 13 and the outer limiter 14 are disposed on the mounting surface 11 of the substrate 10. The inner limiter 13 and the outer limiter 14 are respectively winded around on the mounting surface 11 to form regions. The inner limiter 13 is encompassed in the region that is winded around by the outer limiter 14. The inner limiter 13 and the outer limiter 14 are concentrically disposed on the mounting surface 11.

The region 110 can be further divided into the center area 111 and the periphery area 112 by the inner limiter 13. In other words, the center area 111 is surrounded by the inner limiter 13, and the center area 111 and the periphery area 112 are separated by the inner limiter 13.

For example, the inner limiter 13 is winded around on the mounting surface 11 to form a region (the center area 111). The outer limiter 14 is winded around the inner limiter 13, so that a ring area (i.e., the periphery area 112) between the inner limiter 13 and the outer limiter 14 is formed. In other words, the periphery area 112 surrounds the center area 111, and the periphery area 112 and the center area 111 are separated by the inner limiter 13.

In an exemplary embodiment, a ratio of a diameter of the inner limiter 13 to a diameter of the outer limiter 14 ranges from 1:1.75 to 1:2. However, the present disclosure is not limited thereto.

In an exemplary embodiment, the diameter of the inner limiter 13 ranges from 1.5 mm to 2.0 mm. Preferably, the diameter of the inner limiter 13 ranges from 1.7 mm to 1.9 mm. The diameter of the outer limiter 14 ranges from 3.0 mm to 3.5 mm. Preferably, the diameter of the outer limiter 14 ranges from 3.2 mm to 3.25 mm. However, the present disclosure is not limited thereto.

Heights of the inner limiter 13 and the outer limiter 14 are preferably higher than a light emitting layer of the light emitting unit 30. In an exemplary embodiment, the height of the inner limiter 13 ranges from 50 μm to 100 μm. The height of the outer limiter 14 ranges from 150 μm to 200 μm. However, the present disclosure is not limited thereto.

In an exemplary embodiment, a width of the inner limiter 13 ranges from 100 μm to 150 μm. A width of the outer limiter 14 ranges from 100 μm to 250 μm. However, the present disclosure is not limited thereto.

The inner limiter 13 can be a metal material or a plastic material. In an exemplary embodiment, the inner limiter 13 is a metal material, and the outer limiter 14 is a plastic material. In an exemplary embodiment, the inner limiter 13 is a plastic material, and the outer limiter 14 is a metal material. In another embodiment, the inner limiter 13 and the outer limiter 14 are plastic materials. However, the present disclosure is not limited thereto.

### Eighth Embodiment

Referring to FIG. 8, the semiconductor assembly of an eighth embodiment of the present disclosure is similar to the semiconductor assembly of the seventh embodiment (FIG. 7). The semiconductor assembly includes the substrate 10, the light emitting unit 30, a Zener chip 70, a second reflective resin layer 80′, and a light transmitting layer 90.

The difference between the seventh embodiment and the fifth embodiment is that the Zener chip 70 is encapsulated by the second reflective resin layer 80′, and the periphery area 112 is completely covered by the second reflective resin layer 80′.

In the eighth embodiment, the second reflective resin layer 80′ is disposed between the inner limiter 13 and the outer limiter 14 (the periphery area 112), and has a listric surface formed on the mounting surface 11 (as shown in FIG. 8). Relative to the mounting surface 11, a height of the second reflective resin layer 80′ near the inner limiter 13 is lower than a height of the second reflective resin layer 80′ near the outer limiter 14.

In another exemplary embodiment, the second reflective resin layer 80′ can have a concave surface formed on the mounting surface 11 and between the inner limiter 13 and the outer limiter 14 (the periphery area 112). In other words, relative to the mounting surface 11, the height of the second reflective resin layer 80′ near the inner limiter 13 is higher than the height of the second reflective resin layer 80′ near the outer limiter 14. However, the present disclosure is not limited thereto.

The second reflective resin layer 80′ is a light transmitting layer which is permeable to light beam. A material of the second reflective resin layer 80′ contains a second silicon-based resin, a UV absorber, and reflective particles.

Specifically, the second silicon-based resin can optionally be a silicon-based resin including methyl group or a thermosetting silicon-based resin according to various requirements. For example, the second silicon-based resin can be a methyl silicon resin, a methyl phenyl vinyl silicon resin, or a combination thereof. The UV absorber, the reflective particles, and the HALS are the same as those mentioned above, so it is not repeated herein.

In an exemplary embodiment, based on a total weight of the second silicon-based resin being 100 phr, an amount of the UV absorber in the second reflective resin layer 80′ ranges from 0.1 phr to 2 phr, such as 0.2 phr, 0.4 phr, 0.6 phr, 0.8 phr, 1.0 phr, 1.2 phr, 1.4 phr, 1.6 phr, or 1.8 phr.

In an exemplary embodiment, based on a total weight of the second silicon-based resin being 100 phr, an amount of the reflective particles in the second reflective resin layer 80′ ranges from 5 phr to 75 phr, such as 15 phr, 25 phr, 35 phr, 45 phr, 55 phr, or 65 phr.

In addition to the second silicon-based resin, the UV absorber, and the reflective particles, the second reflective resin layer 80′ can further include a hindered amine light stabilizer (HALS).

In an exemplary embodiment, based on a total weight of the second silicon-based resin being 100 phr, an amount of the HALS in the second reflective resin layer 80′ ranges from 0.1 phr to 15 phr, such as 3 phr, 6 phr, 9 phr, or 12 phr.

Relative to the mounting surface 11, a thickness H6 of the second reflective resin layer 80′ can range from 150 μm to 200 μm, such as 160 μm, 170 μm, 180 μm, or 190 μm.

In order to prove that the semiconductor assembly of the present disclosure has a high reliability, the semiconductor assembly in Examples 10 and 11 are respectively manufactured according to the seventh embodiment and the eighth embodiment. The semiconductor assembly in Comparative Example 6 is manufactured according to the structure shown in FIG. 11.

The difference between the semiconductor assemblies in Comparative Example 6 and Examples 10 and 11 is that the first reflective resin layer 80 and the second reflective resin layer 80′ are absent from the semiconductor assemblies in Comparative Example 6. In other words, the Zener chip 70 in Comparative Example 6 is not encapsulated by the first reflective resin layer 80 or the second reflective resin layer 80′.

In Examples 10 and 11, the reflective particles, the UV absorber, and the HALS are the same as those mentioned above, so it is not repeated herein. Specific components of the first reflective resin layer 80 or the second reflective resin layer 80′ in Examples 10 and 11 are listed in Table 6. The material of the light transmitting layer 90 in Examples 10 and 11 and Comparative Example 6 is a fluoropolymer. Luminous efficiency and the reliability of the semiconductor assembly in Examples 10 and 11 and Comparative Example 6 are measured and listed in Table 6. In the luminous efficiency test, the light intensity of the semiconductor assembly in Comparative Example 6 is defined as 100%.

The thickness H6 of the second reflective resin layer 80′ ranges from 150 μm to 200 μm. If the thickness H6 of the second reflective resin layer 80′ is too thick, a space for the light transmitting layer 90 will be compressed, and then the luminous efficiency of the semiconductor assembly is decreased. If the thickness H6 of the second reflective resin layer 80′ is too thin, the Zener chip 70 cannot be protected, and the reliability of the semiconductor assembly cannot be enhanced.

TABLE 6

| | | | Exam- | Exam- | Comparative |
|---|---|---|---|---|---|
| (phr) | | | ple 10 | ple 11 | Example 6 |
| First | First silicon-based resin | | 100 | — | — |
| reflective | Reflective particles | | 40 | — | — |
| resin layer | UV absorber | | 1 | — | — |
| | HALS | | 1 | — | — |
| Second | Second silicon-based | | — | 100 | — |
| reflective | resin | | | | |
| resin layer | Reflective particles | | — | 40 | — |
| | UV absorber | | — | 1 | — |
| | HALS | | — | 1 | — |
| Property | Luminous efficiency test | | 88% | 91% | 100% |
| of semi- | Reliability | 0 hours | 100% | 100% | 100% |
| conductor | test | 168 hours | 99.5% | 102.6% | 95.3% |
| assembly | | 336 hours | 98.0% | 102.5% | 91.1% |
| | | 504 hours | 97.8% | 102.4% | 89.8% |
| | | 672 hours | 95.1% | 102.1% | 85.6% |
| | | 840 hours | 93.2% | 101.8% | 83.1% |
| | | 1008 hours | 92.4% | 98.9% | 82.07% |

According to the result of Table 6, due to the first reflective layer 80 or the second reflective layer 80′ encapsulating the Zener chip 70, the reliability of the semiconductor assembly can be enhanced and the luminous efficiency of the semiconductor assembly can be adequately maintained.

### Ninth Embodiment

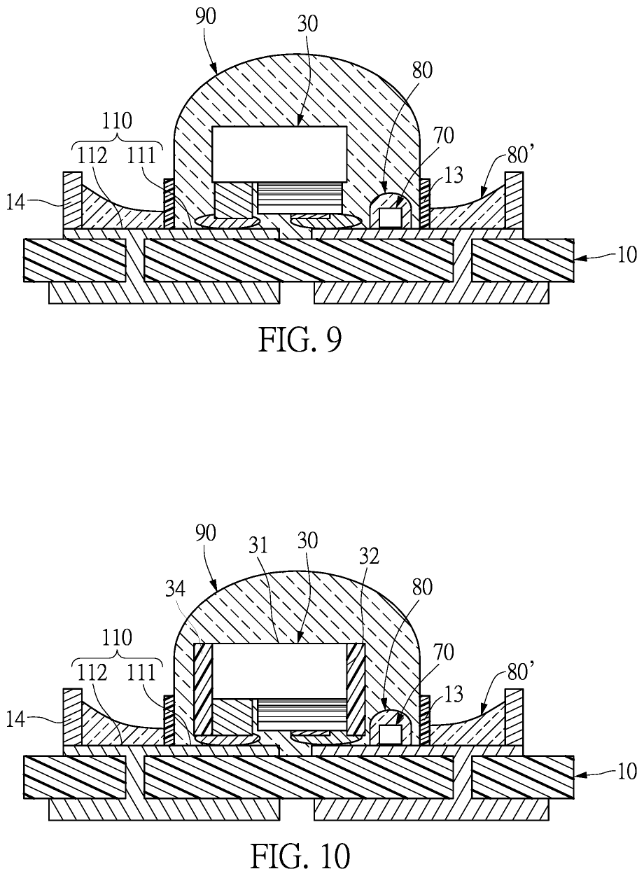

Referring to FIG. 9, the semiconductor assembly of a ninth embodiment of the present disclosure is similar to the semiconductor assembly of the eighth embodiment (FIG. 8). The semiconductor assembly includes the substrate 10, the light emitting unit 30, the Zener chip 70, the first reflective resin layer 80, the second reflective resin layer 80′, and the light transmitting layer 90.

The difference between the ninth embodiment and the eighth embodiment is that the Zener chip is located at the center area 111, and the Zener chip is encapsulated by the first reflective resin layer 80. Therefore, the light emitting unit 30, the Zener chip 70, and the first reflective resin layer 80 are encapsulated by the light transmitting layer 90.

In the ninth embodiment, the second reflective resin layer 80′ surrounds the light transmitting layer 90 to form a dense waterproof layer, thereby protecting the light emitting unit 30 or the Zener chip 70 from contacting the vapor or air in the environment.

### Tenth Embodiment

Referring to FIG. 10, the semiconductor assembly of a tenth embodiment of the present disclosure is similar to the semiconductor assembly of the ninth embodiment (FIG. 9). The semiconductor assembly includes the substrate 10, the light emitting unit 30, the Zener chip 70, the first reflective resin layer 80, the second reflective resin layer 80′, and the light transmitting layer 90. The difference between the tenth embodiment and the ninth embodiment is that the light emitting unit 30 is surrounded by the reflective layer 34.

The reflective layer 34 is formed on the side light emitting surface 32 of the light emitting unit 30 so as to concentrate the light beam emitted from the light emitting unit 30. The reflective layer 34 can protect the light emitting unit 30 from contacting vapor in the environment. A material of the light emitting unit 30 includes a light transmitting resin and reflective particles, such as a silicon-based resin and PTFE particles. In order to prove that the semiconductor assembly of the present disclosure has a high reliability, the semiconductor assembly in Examples 12 and 13 are respectively manufactured according to the ninth embodiment and the tenth embodiment. The semiconductor assembly in Comparative Example 6 is manufactured according to the structure shown in FIG. 11.

The difference between the semiconductor assemblies in Comparative Example 6 and Examples 12 and 13 is that the first reflective resin layer 80 is absent from the semiconductor assemblies in Comparative Example 6. In other words, the Zener chip 70 in Comparative Example 6 is not encapsulated by the first reflective resin layer 80.

In Examples 12 and 13, the reflective particles, the UV absorber, and the HALS are the same as those mentioned above, so it is not repeated herein. Specific components of the first reflective resin layer 80 and the second reflective resin layer 80′ in Examples 12 and 13 are listed in Table 7. The material of the light transmitting layer 90 in Examples 12 and 13 and Comparative Example 6 is a fluoropolymer. Luminous efficiency and the reliability of the semiconductor assembly in Examples 12 and 13 and Comparative Example 6 are measured and listed in Table 7. In the luminous efficiency test, the light intensity of the semiconductor assembly in Comparative Example 6 is defined as 100%.

TABLE 7

| | | | Exam- | Exam- | Comparative |
|---|---|---|---|---|---|
| (phr) | | | ple 12 | ple 13 | Example 6 |
| First | First silicon-based resin | | 100 | 100 | — |
| reflective | Reflective particles | | 40 | 40 | — |
| resin layer | UV absorber | | 1 | 1 | — |
| | HALS | | 1 | 1 | — |
| Second | Second silicon-based | | 100 | 100 | — |
| reflective | resin | | | | |
| resin layer | Reflective particles | | 40 | 40 | — |
| | UV absorber | | 1 | 1 | — |
| | HALS | | 1 | 1 | — |
| Reflective | Light transmitting | | — | 60 | — |
| layer | silicon resin | | | | |
| | Reflective particles | | — | 40 | — |
| Property | Luminous efficiency test | | 93% | 98% | 100% |
| of semi- | Reliability | 0 hours | 100% | 100% | 100% |
| conductor | test | 168 hours | 102.2% | 102.3% | 95.3% |
| assembly | | 336 hours | 101.4% | 102.1% | 91.1% |
| | | 504 hours | 100.4% | 101.8% | 89.8% |
| | | 672 hours | 99.2% | 101.1% | 85.6% |
| | | 840 hours | 98.3% | 99.7% | 83.1% |
| | | 1008 hours | 97.9% | 98.2% | 82.07% |

According to the result of Table 7, the reflective layer 34 formed on the light emitting unit 30 can protect the light emitting unit 30 and enhance the luminous efficiency and the reliability of the semiconductor assembly.

The disposition of the reflective resin layer 40, the first reflective resin layer 80, or the second reflective resin layer 80′ can prevent a silicone resin from damaging through the physical reflection mechanism and the chemical absorption mechanism. Therefore, the semiconductor assembly of the present disclosure can have good reliability and adequate luminous efficiency.

The disposition of the inner limiter 13 and the outer limiter 14 can define the center area 111 and the periphery area 112 and arrange the first reflective resin layer 80, the second reflective resin layer 80′, and the light transmitting layer 90 in different regions, such that the reliability of the semiconductor assembly can be enhanced.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A semiconductor assembly, comprising:
a substrate having a mounting surface;
a retaining wall disposed on the mounting surface and having an inner surface; wherein an accommodation space is defined by the inner surface and the mounting surface;
a light emitting unit disposed in the accommodation space and disposed on the mounting surface; wherein the light emitting unit has an upper light emitting surface and a side light emitting surface; and
a reflective resin layer disposed in the accommodation space and disposed between the inner surface and the side light emitting surface; wherein the reflective resin layer contains a based resin, a UV absorber, and reflective particles.

2. The semiconductor assembly according to claim 1, wherein, relative to the mounting surface, a height of the reflective resin layer near the side light emitting surface is lower than or equal to a height of the upper light emitting surface.

3. The semiconductor assembly according to claim 1, wherein the reflective resin layer contacts the side light emitting surface and the inner side surface, and relative to the mounting surface, a height of the reflective resin layer near the side light emitting surface is lower than a height of the reflective resin layer near the inner side surface.

4. The semiconductor assembly according to claim 1, wherein the reflective resin layer has a listric surface or a concave surface between the retaining wall and the light emitting unit.

5. The semiconductor assembly according to claim 1, wherein, relative to the mounting surface, a thickness of the reflective resin layer near the side light emitting surface ranges from 180 μm to 300 μm.

6. The semiconductor assembly according to claim 1, wherein, based on a total weight of the based resin being 100 phr, an amount of the UV absorber ranges from 0.1 phr to 15 phr.

7. The semiconductor assembly according to claim 1, wherein, based on a total weight of the based resin being 100 phr, an amount of the reflective particles ranges from 5 phr to 75 phr.

8. The semiconductor assembly according to claim 1, wherein the reflective resin layer further contains a hindered amine light stabilizer.

9. The semiconductor assembly according to claim 8, wherein based on a total weight of the based resin being 100 phr, an amount of the hindered amine light stabilizer ranges from 0.1 phr to 15 phr.

10. The semiconductor assembly according to claim 1, further comprising a first light transmitting layer disposed between the substrate and the reflective layer, wherein the first light transmitting layer contains a first based resin and a UV absorber.

11. The semiconductor assembly according to claim 10, wherein, based on a total weight of the first based resin being 100 phr, an amount of the UV absorber ranges from 0.1 phr to 2 phr.

12. The semiconductor assembly according to claim 10, wherein, relative to the mounting surface, a thickness of the first light transmitting layer near the side light emitting surface ranges from 50 μm to 100 μm.

13. The semiconductor assembly according to claim 10, wherein the first light transmitting layer further contains a hindered amine light stabilizer, and based on a total weight of the first based resin being 100 phr, an amount of the hindered amine light stabilizer ranges from 0.1 phr to 15 phr.

14. The semiconductor assembly according to claim 10, wherein further comprising a second light transmitting layer disposed between the substrate and the first light transmitting layer, wherein the second light transmitting layer contains a second based resin and a UV absorber, and an amount of the UV absorber in the second light transmitting layer is larger than an amount of the UV absorber in the first light transmitting layer.

15. The semiconductor assembly according to claim 14, wherein, based on a total weight of the second based resin being 100 phr, the amount of the UV absorber in the second light transmitting layer ranges from 5 phr to 15 phr.

16. The semiconductor assembly according to claim 14, wherein, relative to the mounting surface, a thickness of the second light transmitting layer near the side light emitting surface ranges from 70 μm to 150 μm.

17. The semiconductor assembly according to claim 14, wherein the second light transmitting layer further contains a hindered amine light stabilizer, and based on a total weight of the second based resin being 100 phr, an amount of the hindered amine light stabilizer ranges from 0.1 phr to 15 phr.

18. The semiconductor assembly according to claim 1, wherein the based resin is a methyl silicon resin, a methyl phenyl vinyl silicon resin, or a combination thereof.

19. The semiconductor assembly according to claim 1, wherein a protection layer is formed on the upper light emitting surface and the side light emitting surface of the light emitting unit, and the protection layer contains a light transmitting silicon resin.
